(19) United States
(12) Patent Application Publication
(10) Pub. No.: US 2012/0192911 A1
(43) Pub. Date: Aug. 2, 2012

(54) THIN-FILM SOLAR CELL

(75) Inventors: Makoto SHIMOSAWA, Arao-City (JP); Nobuyuki MASUDA, Tamana-city (JP)

(73) Assignee: FUJI ELECTRIC SYSTEMS CO., LTD., Tokyo (JP)

(21) Appl. No.: 12/978,206

(22) Filed: Dec. 23, 2010

(30) Foreign Application Priority Data
Apr. 28, 2010 (JP) 2010-104373
Sep. 15, 2010 (JP) 2010-206879

(51) Int. Cl. H01L 31/05

(52) U.S. Cl. 136/244

(57) ABSTRACT

A thin-film solar cell includes a plurality of unit solar cells, each unit solar cell including a photoelectric conversion portion and a rear electrode layer. The photoelectric conversion portion has a first electrode layer, a photoelectric conversion layer, and a second transparent electrode layer, sequentially stacked on a front surface of the insulating substrate. The rear electrode layer is stacked on a rear surface of the insulating substrate. Each unit solar cell has a first overlap region in which a portion of the first electrode layer, taken from a plan view, overlaps with a portion of the rear electrode layer of an adjacent unit solar cell. Each unit solar cell has a second overlap region in which the photoelectric conversion portion and the rear electrode layer of each unit solar cell, taken from a plan view, overlap with each other.

### CROSS-REFERENCE TO RELATED APPLICATION

This application claims priority under 35 U.S.C. §119 from Japanese Patent Application No. 2010-104373, filed on Apr. 28, 2010, and Japanese Patent Application No. 2010-206879, filed on Sep. 15, 2010, the entirety of which is incorporated herein by reference.

### BACKGROUND OF THE INVENTION

1. Field of the Invention

The present invention relates to a solar cell that uses sunlight to generate power, and more particularly, to a thin-film solar cell having a structure in which multiple unit solar cells (unit cells) are connected in series to one another.

2. Description of the Related Art

In recent years, solar cells have drawn attention as one of means for solving global environmental problems. Among the solar cells, a solar cell including a photoelectric conversion layer made of amorphous silicon, microcrystalline silicon, a compound, such as CdTe (cadmium telluride) or CIGC (copper-indium-gallium-selenide), or an organic material has an advantage of being able to significantly reduce the amount of material used, as compared to other types of solar cells according to the related art. The reason is that the thin photoelectric conversion layer in such solar cell can be realized in a thin film having a thickness of about several hundreds of nanometers (nm) to several micrometers (μm). Therefore, such solar cell has drawn attention in terms of a low manufacturing cost. This solar cell is called a thin-film solar cell. In addition, a further advantage of the thin-film solar cell is that the thin-film solar cell can be formed on various kinds of substrates, unlike the crystalline silicon solar cell according to the related art.

Since the voltage generated by a single solar cell is low, a structure is generally used in which multiple unit solar cells (unit cells) are connected in series to one another to increase the generated voltage. In the case of the thin-film solar cell, in general, an electrode layer and a photoelectric conversion layer are formed on one substrate and each of the formed layers is divided into multiple unit cells by, for example, laser patterning, thereby achieving a structure in which the unit cells are connected in series to one another. For example, Japanese Patent Application Laid-Open (JP-A) No. 10-233517 discloses a thin-film solar cell, in which multiple unit cells are formed on a sheet (film) substrate and the unit cells are connected in series to one another by current collection holes and connection holes passing through the sheet (film) substrate. The solar cell structure is called a Series-Connection through Apertures formed on Film (SCAF) structure.

FIG. 12 is a plan view illustrating a thin-film solar cell having the SCAF structure according to the related art. FIGS. 13A to 13G are cross-sectional views (corresponding to cross-sectional views taken along the line Y-Y of FIG. 12) illustrating a process sequence of a method of manufacturing the thin-film solar cell having the SCAF structure according to the related art. In FIGS. 13A to 13G, the electrode layers that come to have the same potential when the thin-film solar cell receives light and generates power are hatched in the same manner.

As illustrated in FIG. 12 and FIGS. 13A to 13G, a thin-film solar cell 70 includes an insulating substrate 71. A photoelectric conversion portion 75 including a first electrode layer 72, a photoelectric conversion layer 73, and a second electrode layer 74 stacked in this order, is formed on the front surface of the insulating substrate 71, and a rear electrode layer 78 including a third electrode layer 76 and a fourth electrode layer 77 stacked in this order is formed on the rear surface of the insulating substrate 71. In the thin-film solar cell 70 illustrated in FIG. 12 and FIGS. 13A to 13G, the first electrode layer 72 and the photoelectric conversion layer 73 are formed in the same range of the front surface of the insulating substrate 71, and the third electrode layer 76 and the fourth electrode layer 77 are formed in the same range of the rear surface of the insulating substrate 71. In addition, each end of the front surface of the insulating substrate 71 in the horizontal direction of FIG. 12 is provided with a portion having a double layer structure of the first electrode layer 72 and the photoelectric conversion layer 73. The entire central portion of the front surface of the insulating substrate 71 other than the double layer portions is further provided with the second electrode layer 74 stacked on the photoelectric conversion layer 73. That is, the central portion is provided with the photoelectric conversion portion 75 having a triple layer structure of the first electrode layer 72, the photoelectric conversion layer 73, and the second electrode layer 74.

Each layer on the front surface and the rear surface of the insulating substrate 71 is linearly removed and divided into multiple portions. In this way, multiple unit cells (UCs), each having the photoelectric conversion portion 75 and the rear electrode layer 78, are formed on the insulating substrate 71.

In each of the unit cells (UCs), the second electrode layer 74 and the rear electrode layer 78 (the third electrode layer 76 and the fourth electrode layer 77) are electrically connected to each other through current collection holes 79.

A first linearly removed portion 81 that divides each layer (the first electrode layer 72, the photoelectric conversion layer 73, and the second electrode layer 74) formed on the front surface of the insulating substrate 71 is misaligned in position by a predetermined distance with a second linearly removed portion 82 that divides the rear electrode layer 78 (the third electrode layer 76 and the fourth electrode layer 77) formed on the rear surface of the insulating substrate 71, with the insulating substrate 71 interposed therebetween. Therefore, the first electrode layer 72 of one unit cell (UCₙ) of two adjacent unit cells (UCₙ and UCₙ₊₁) is electrically connected to the rear electrode layer 78 of the other unit cell (UCₙ₊₁) through collection holes 80.

In this way, the unit cell (UCₙ) can be electrically connected in series to an adjacent unit cell (UCₙ₊₁) through the connection holes 80 and the rear electrode layer 78.

Next, the process sequence of the method of manufacturing the thin-film solar cell according to the related art will be described with reference to FIGS. 13A to 13G.

First, as illustrated in FIG. 13A, multiple connection holes 80 are formed in the insulating substrate 71 at predetermined positions. For example, a polyimide-based film, a polyethylene naphthalate (PEN)-based film, a polyether sulfone (PES)-based film, a polyethylene terephthalate (PET)-based film, or an aramid-based film may be used as the insulating substrate 71. Each of the connection holes 80 is circular in shape and 1 mm in diameter. The connection holes 80 may be formed by a mechanical means such as punching.

Then, as illustrated in FIG. 13B, the first electrode layer 72 is formed on the front surface of the insulating substrate 71, and the third electrode layer 76 is formed on the rear surface of the insulating substrate 71. For this instance, the first electrode layer 72 and the third electrode layer 76 overlap each other so as to be electrically connected to each other on the inner circumferential surface of the connection hole 80.

Then, as illustrated in FIG. 13C, multiple current collection holes 79 are formed in the insulating substrate 71. Similar to the connection hole 80, the current collection hole 79 is circular in shape and 1 mm in diameter. The current collection hole 79 may be formed by a mechanical means such as punching.

Then, as illustrated in FIG. 13D, the photoelectric conversion layer 73 is formed on the first electrode layer 72. The photoelectric conversion layer 73 is a thin semiconductor layer. For example, an amorphous silicon (a-Si) film may be used as the photoelectric conversion layer 73.

Then, as illustrated in FIG. 13E, the second electrode layer 74 is formed on the photoelectric conversion layer 73. The second electrode layer 74 is a transparent electrode layer. For example, an indium tin oxide (ITO) film may be used as the second electrode layer 74. When the second electrode layer 74 is formed, the connection hole 80 and a peripheral region thereof are covered with a mask such that the second electrode layer 74 is not formed in a portion in which the connection hole 80 is formed.

Then, as illustrated in FIG. 13F, the fourth electrode layer 77 is formed on the third electrode layer 76 that is formed on the rear surface of the insulating substrate 71. The fourth electrode layer 77 is a low-resistance conductive layer. For example, a low-resistance metal film may be used as the fourth electrode layer 77. In this case, the second electrode layer 74 and the fourth electrode layer 77 overlap each other so as to be electrically connected to each other on the inner circumferential surface of the current collection hole 79.

The photoelectric conversion portion 75 including the first electrode layer 72, the photoelectric conversion layer 73, and the second electrode layer 74 is formed on the front surface of the insulating substrate 71 and the rear electrode layer 78 including the third electrode layer 76 and the fourth electrode layer 77 is formed on the rear surface of the insulating substrate 71 by the above-mentioned process.

Then, as illustrated in FIG. 13G, each layer formed on the front surface of the insulating substrate 71 is linearly removed to form the first linearly removed portion 81, and each layer formed on the rear surface of the insulating substrate 71 is linearly removed to form the second linearly removed portion 82. In this way, multiple unit cells (UCs), each having the photoelectric conversion portion 75 formed on the front surface of the insulating substrate 71 and the rear electrode layer 78 formed on the rear surface of the insulating substrate 71, are formed on the insulating substrate 71. As described above, in each of the unit cells (UCs), the second electrode layer 74 and the fourth electrode layer 77 (that is, the rear electrode layer 78) are electrically connected to each other through the current collection holes 79, and the first electrode layer 72 of one unit cell (UCₙ) of two adjacent unit cells (UCs) is electrically connected to the third electrode layer 76 (that is, the rear electrode layer 78) of the other unit cell (UCₙ₊₁) through the connection holes 80.

When light is emitted to the thin-film solar cell 70 and carriers (electrons and holes) are generated in the photoelectric conversion layer 73 of each unit cell (UC), one type of carriers of the two types of carriers flow to the second electrode layer (transparent electrode layer) 74 by the electric field in the p-n junction. Since the second electrode layer 74 is electrically connected to the fourth electrode layer 77 (the rear electrode layer 78) on the inner circumferential surface of the current collection hole 79, the carriers that have flowed to the second electrode layer 74 further move to the rear surface of the insulating substrate 71 through the current collection hole 79. Since the photoelectric conversion layer 73 can be substantially regarded as an insulating layer, the first electrode layer 72 and the second electrode layer 74 are substantially insulated from each other. The carriers that have moved to the rear surface of the insulating substrate 71 still further move to the connection hole 80. The second electrode layer 74 is not formed in a portion in which the connection hole 80 is formed, and the first electrode layer 72 and the third electrode layer 76 (the rear electrode layer 78) are electrically connected to each other on the inner circumferential surface of the connection hole 80. Therefore, the carriers yet further move to the front surface of the insulating substrate 71 through the connection hole 80. Then, the carriers move to the photoelectric conversion layer 73 of an adjacent unit cell (UC) on the front surface of the insulating substrate 71. As such, in the thin-film solar cell 70 having the SCAF structure according to the related art, multiple unit cells (UCs) are connected in series to one another through the current collection holes 79 and the connection holes 80.

In the thin-film solar cell according to the related art, in each unit cell, the second electrode layer, which is a transparent electrode layer, and the rear electrode layer are electrically connected to each other through the current collection holes, and the power loss (current collection loss) of the transparent electrode layer with high resistance is reduced a little.

However, in the thin-film solar cell according to the related art, the arrangement of the current collection holes is not examined. Therefore, in the thin-film solar cell according to the related art, the travel distance of the carriers generated from the photoelectric conversion portion (unit photoelectric conversion portion) in each unit cell, from the high-resistance transparent electrode layer to the current collection hole, is long, which results in large current collection loss. In addition, since it is considered that the arrangement of the current collection holes affects the output characteristics of the thin-film solar cell, it is preferable that the arrangement of the current collection holes be as close to optimal as possible.

### SUMMARY OF THE INVENTION

The invention has been made in order to solve the above-mentioned problems and an object of the invention is to provide a thin-film solar cell that has a structure in which multiple unit solar cells are connected in series to one another and optimizes the arrangement of current collection holes to improve conversion efficiency, as compared to the related art.

According to an aspect of the invention, a thin-film solar cell includes multiple unit solar cells each of which includes a photoelectric conversion portion having a first electrode layer, a photoelectric conversion layer, and a second transparent electrode layer sequentially formed on a front surface of an insulating substrate and a rear electrode layer formed on a rear surface of the insulating substrate. Each of the unit solar cells is arranged so as to have a first overlap region in which a portion of the first electrode layer, which does not form the photoelectric conversion portion, in one of two adjacent unit solar cells is opposite to a portion of the rear electrode layer of the other unit solar cell with the insulating substrate interposed therebetween. The second electrode layer and the rear electrode layer are electrically connected to each other through multiple current collection holes passing through the insulating substrate in each unit solar cell, and the first electrode layer of one of two adjacent unit solar cells and the rear electrode layer of the other unit solar cell are electrically connected to each other in the first overlap region through at least one connection hole passing through the insulating substrate, thereby connecting the multiple unit solar cells in series. The multiple current collection holes are arranged such that the current collection holes are distributed in a second overlap region in which the photoelectric conversion portion and the rear electrode layer forming each unit solar cell are opposite to each other with the insulating substrate interposed therebetween and the gaps between the closest current collection holes are equal to each other.

The inventors examined the arrangement of the current collection holes in the thin-film solar cell. The examination result proved that, when multiple current collection holes were arranged such that the current collection holes were distributed in a target region (that is, a region in which the current collection holes could be arranged) and the gaps between the closest current collection holes was equal to each other, the output of the thin-film solar cell was improved, as compared to different arrangements. Therefore, according to the thin-film solar cell according to the invention, the arrangement of the current collection holes is optimized to improve the output characteristics (conversion efficiency) of the thin-film solar cell.

### BRIEF DESCRIPTION OF THE DRAWINGS

FIG. 1 is a plan view illustrating the schematic structure of a thin-film solar cell according to an embodiment of the invention;

FIG. 2 includes exploded perspective views (a) to (d) illustrating the thin-film solar cells according to a first embodiment of the invention;

FIG. 3 is a cross-sectional view taken along the line X-X of FIG. 1;

FIG. 4 is a diagram schematically illustrating current collection holes arranged in a lattice;

FIG. 5 is a diagram illustrating the relationship between the number of rows of the current collection holes and the output (Pmax) of the thin-film solar cell when the aperture ratio is 2%;

FIG. 6 is a diagram illustrating the relationship between the number of rows of the current collection holes and the output (Pmax) of the thin-film solar cell when the aperture ratio is 4%;

FIG. 7 is a diagram illustrating the relationship between the number of rows of the current collection holes and the output (Pmax) of the thin-film solar cell when the aperture ratio is 1%;

FIG. 8 is a diagram illustrating the relationship between the diameter of the current collection hole and the output (Pmax) of the thin-film solar cell;

FIG. 9 is a diagram schematically illustrating the current collection holes arranged in a staggered arrangement;

FIG. 10 is a plan view illustrating the schematic structure of a thin-film solar cell including current collection holes arranged in a staggered arrangement;

FIG. 11 is a diagram illustrating the relationship between the number of rows of the current collection holes and the output (Pmax) of the thin-film solar cell when the current collection holes are arranged in a staggered arrangement;

FIG. 12 is a plan view illustrating a thin-film solar cell according to the related art; and

FIGS. 13A to 13G are cross-sectional views illustrating a process sequence of a method of manufacturing the thin-film solar cell according to the related art taken along the line Y-Y of FIG. 12.

### DESCRIPTION OF THE PREFERRED EMBODIMENTS

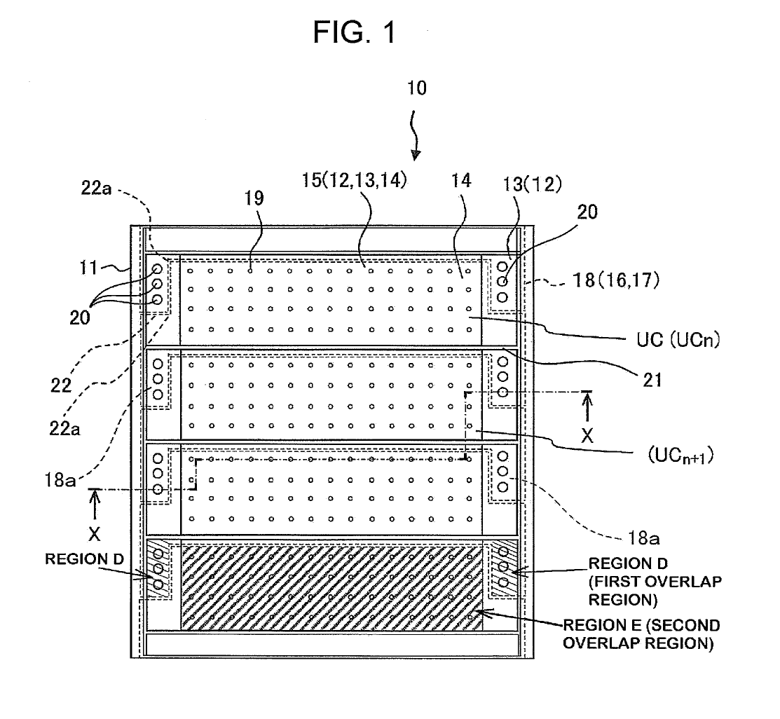

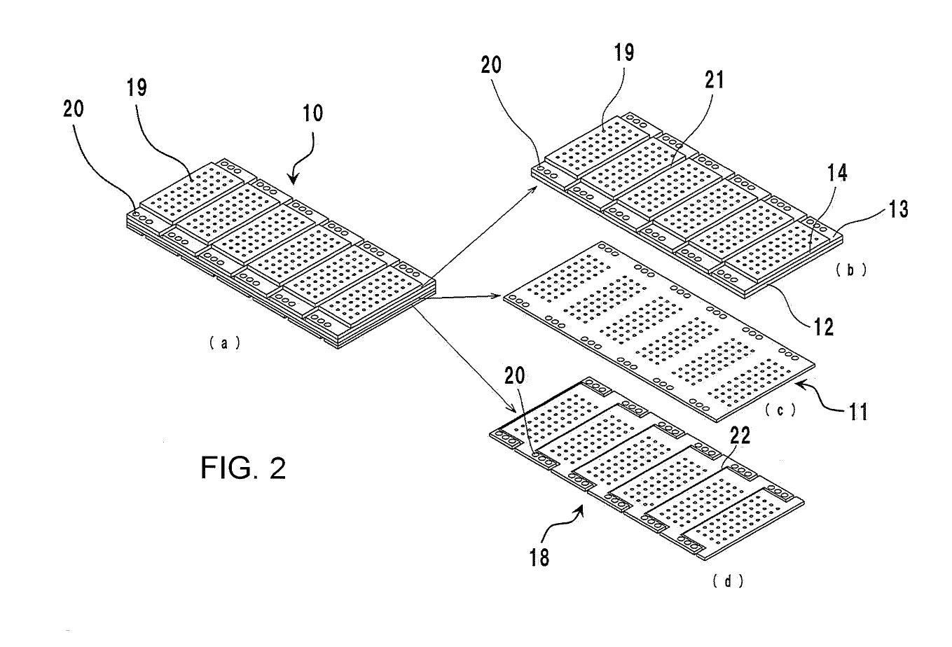

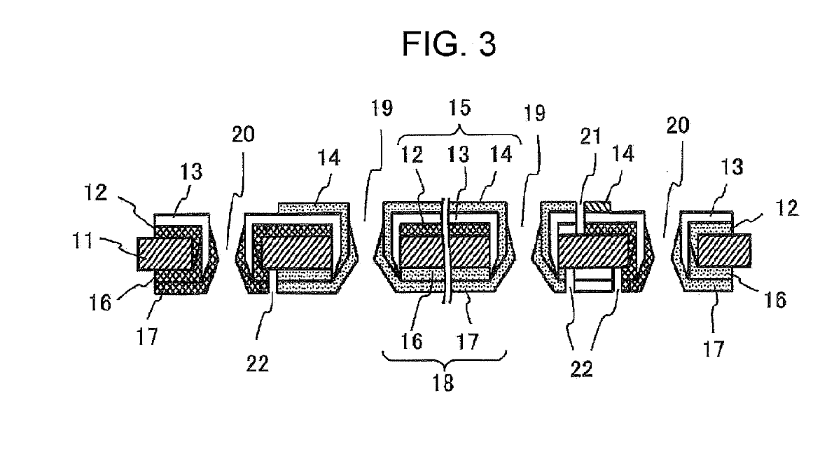

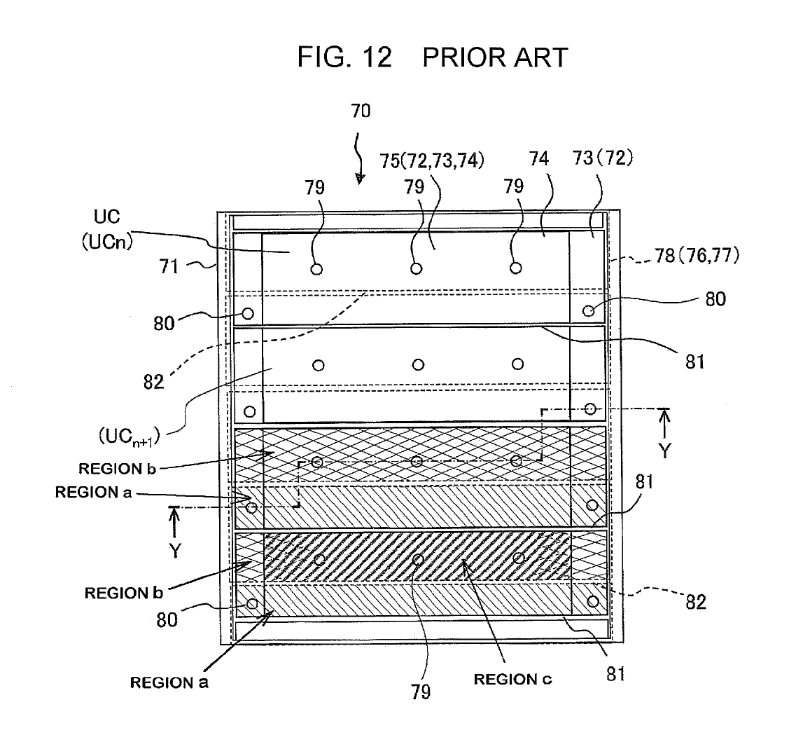

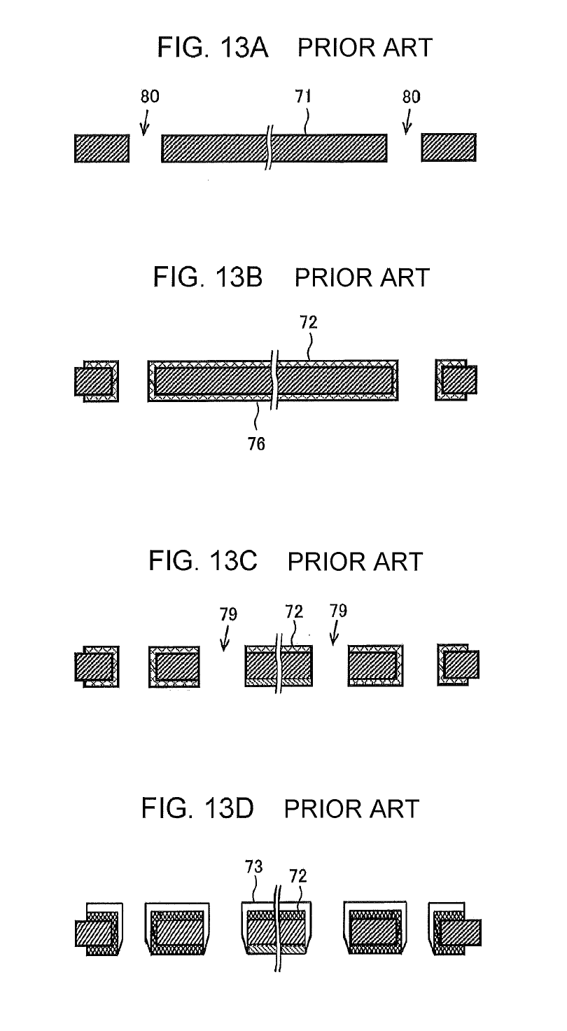

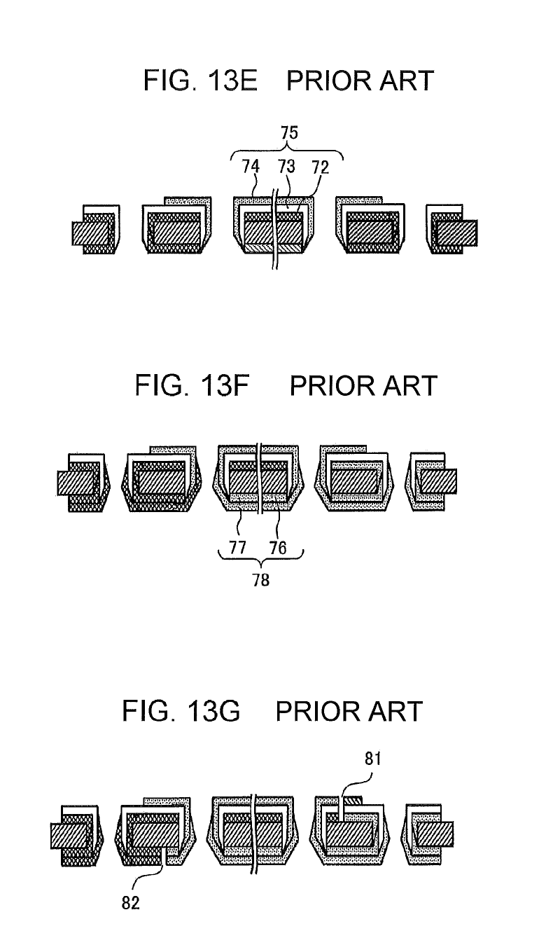

Hereinafter, exemplary embodiments of the invention will be described with reference to the accompanying drawings. FIG. 1 is a plan view illustrating the schematic structure of a thin-film solar cell 10 according to an embodiment of the invention. FIG. 2 includes exploded perspective views (a) to (d) of FIG. 1. FIG. 3 is a cross-sectional view taken along the line X-X of FIG. 1. The thin-film solar cell 10 according to this embodiment has an SCAF structure, and the basic structure of the thin-film solar cell 10 is the same as that of the thin-film solar cell 70 according to the related art illustrated in FIG. 12 and FIGS. 13A to 13G. Briefly, the thin-film solar cell 10 includes a flexible insulating substrate 11. A photoelectric conversion portion 15 having a first electrode layer 12, a photoelectric conversion layer 13, and a second electrode layer 14 sequentially stacked is provided on the front surface of the insulating substrate 11, and a rear electrode layer 18 having a third electrode layer 16 and a fourth electrode layer 17 sequentially stacked is provided on the rear surface of the insulating substrate 11.

In FIG. 2, exploded view (a) illustrates the overall structure of the thin-film solar cell, and exploded view (b) illustrates a laminated structure of the first electrode layer 12, the photoelectric conversion layer 13, and the second electrode layer 14 formed on the insulating substrate 11. In addition, exploded view (c) of FIG. 2 illustrates the insulating substrate 11, and exploded view (d) of FIG. 2 illustrates the shape of the rear electrode layer 18 formed on the rear surface of the insulating substrate 11.

Each of the layers provided on the front and rear surfaces of the insulating substrate 11 is linearly removed and divided into multiple portions by, for example, a laser patterning process. In this way, multiple unit solar cells (unit cells: UCs), each having the unit photoelectric conversion portion 15 formed on the front surface of the insulating substrate 11 and the rear electrode layer 18 formed on the rear surface of the insulating substrate 11, is formed on the insulating substrate 11. In each of the layers provided on the front surface of the insulating substrate 11, the linearly removed portion (solid line) is a first linearly removed portion 21. In each of the layers provided on the rear surface of the insulating substrate 11, the linearly removed portion (dashed line) is a second linearly removed portion 22. The shapes of the first linearly removed portion 21 and the second linearly removed portion 22 will be described below.

In each unit cell (UC), the second electrode layer 14 and the fourth electrode layer 17 are electrically connected to each other through multiple current collection holes 19. Of two adjacent unit cells (UCₙ And UCₙ₊₁), a portion of the first electrode layer 12 in a region (that is, a region that is not formed in a triple layer structure) of one unit cell (UCₙ) in which the photoelectric conversion portion is not formed and a portion of the third electrode layer 16 in the other unit cell (UCₙ₊₁) are electrically connected to a region, in which they are opposite to each other with the insulating substrate interposed therebetween, through connection holes 20. In this way, the thin-film solar cell according to this embodiment also has a structure in which multiple unit cells (UCs) are connected in series to one another.

The electrical connection between the first electrode layer 12 of the one unit cell (UCₙ) and the third electrode layer 16 of the other unit cell (UCₙ₊₁) through the connection holes 20 will be described in other words as follows.

Each unit cell is configured so as to have an overlap region (hereinafter, referred to as a “first overlap region”; a region D in FIG. 1) in which a portion of the first electrode layer 12 that does not form the photoelectric conversion portion 15 in one of two adjacent unit cells and a portion of the third electrode layer 16 in the other unit cell are opposite to each other with the insulating substrate 11 interposed therebetween. In the first overlap region, the first electrode layer 12 in one of the two adjacent unit cells and the third electrode layer 16 in the other unit cell are electrically connected to each other through the connection holes 20 passing through the insulating substrate 11.

Next, each component of the thin-film solar cell 10 will be described. For example, the insulating substrate 11 is a plastic substrate and a polyimide-based film, a polyethylene naphthalate (PEN)-based film, a polyether sulfone (PES)-based film, a polyethylene terephthalate (PET)-based film, or an aramid-based film may be used as the plastic substrate. When flexibility is not needed, for example, a glass substrate may be used.

The first electrode layer 12 and the third electrode layer 16 are silver (Ag) layers with a thickness of several hundreds of nanometers (nm) and are formed by a sputtering method. Although not illustrated in the drawings, a texture pattern may be formed on the surface of the first electrode layer 12 in order to diffuse incident light to increase the amount of light absorbed by the photoelectric conversion layer 13. In this embodiment, a silver (Ag) electrode is used as the first electrode layer 12, but the invention is not limited thereto. For example, a film laminate obtained by forming titanium dioxide (TiO₂) having resistance to plasma on the surface of a silver (Ag) electrode, a tin dioxide (SnO₂) film, or a zinc oxide (ZnO) film may be used as the first electrode layer 12. In addition, a material capable of forming the optimal texture pattern may be applied to form the first electrode layer 12.

The photoelectric conversion layer 13 is a thin semiconductor layer. In this embodiment, the photoelectric conversion layer 13 has a double layer tandem structure of amorphous silicon (a-Si) and amorphous silicon germanium (a-SiGe). However, the invention is not limited thereto. For example, the photoelectric conversion layer 13 may be made of amorphous silicon carbide (a-SiC), amorphous silicon oxide (a-SiO), amorphous silicon nitride (a-SiN), microcrystalline silicon (pc-Si), microcrystalline silicon germanium (μc-SiGe), microcrystalline silicon carbide (μc-SiC), microcrystalline silicon oxide (μc-SiO), or microcrystalline silicon nitride (μc-SiN). In addition, the photoelectric conversion layer 13 may be made of a compound-based material or an organic material. Each layer of the photoelectric conversion layer 13 may be formed by, for example, a plasma chemical vapor deposition (plasma CVD) method, a sputtering method, a vapor deposition method, a catalytic chemical vapor deposition (Cat-CVD) method, or a photochemical vapor deposition (photo-CVD) method.

The second electrode layer 14 is a transparent electrode layer and an indium tin oxide (ITO) film formed by the sputtering method is used as the second electrode layer 14 in this embodiment. However, the invention is not limited thereto. For example, a tin dioxide (SnO₂) film or a zinc oxide (ZnO) film may be used as the second electrode layer 14.

The fourth electrode layer 17 is a low-resistance conductive film such as a metal film. In this embodiment, a nickel (Ni) film formed by the sputtering method is used as the fourth electrode layer 17. However, the invention is not limited thereto. The fourth electrode layer 17 may be made of a metal material other than nickel.

The current collection holes 19 are distributed all over the entire overlap region (hereinafter, referred to as a “second overlap region; a region E in FIG. 1) in which the photoelectric conversion portion 15 (unit photoelectric conversion portion) and the rear electrode layer 18 forming each unit cell (UC) are opposite to each other with the insulating substrate 11 interposed therebetween. The connection holes 20 are arranged in the first overlap region (region D). In this embodiment, six connection holes 20 are provided in each unit cell (UC) (three connection holes 20 are provided on each of the left and right sides). The current collection holes 19 and the connection holes 20 are formed by a mechanical means such as punching. In this embodiment, the current collection holes 19 and the connection holes 20 have a circular shape. However, the shapes, sizes, and number of current collection holes 19 and connection holes 20 may appropriately vary depending on the specifications of the thin-film solar cell 10. The arrangement (distribution) of the current collection holes 19 in this embodiment will be described below.

A method of manufacturing the thin-film solar cell 10 according to this embodiment is basically the same as the method (see FIGS. 13A to 13G) of manufacturing the thin-film solar cell according to the related art illustrated in FIG. 12 and the description thereof will not be repeated.

Next, some of the characteristics of the thin-film solar cell 10 according to this embodiment will be described in comparison with the thin-film solar cell (see FIG. 12) according to the related art. In particular, “A. Shape of first linearly removed portion and second linearly removed portion” and “B. Distribution of current collection holes” will be described below.

A. Shape of First Linearly Removed Portion and Second Linearly Removed Portion

As illustrated in FIG. 12, in the thin-film solar cell 70 according to the related art, a first linearly removed portion 81 and a second linearly removed portion 82 are formed in a straight line. The connection holes 80 are arranged in a region a of the regions a and b formed between the first linearly removed portion 81 and the second linearly removed portion 82 in a plan view. If the current collection holes 79 are arranged in the region a, the second electrode layer 74 and the rear electrode layer 78 (the third electrode layer 76 and the fourth electrode layer 77) are electrically connected to each other by the current collection holes 79, and the first electrode layer 73 and the rear electrode layer 78 are electrically connected to each other by the connection holes 80. As a result, the first electrode layer 73 is electrically connected to the second electrode layer 74, and leakage occurs. Therefore, the current collection holes 79 need to be arranged in the region b different from the region a in which the connection holes 80 are arranged. As a result, in the thin-film solar cell 70 according to the related art, the region in which the current collection holes 79 can be formed is limited to a region c in which the unit photoelectric conversion portion (75) is formed and the region b and the unit photoelectric conversion portion (75) overlap each other. In this case, the travel distance of carriers generated from the unit photoelectric conversion portion 75 in the region a other than the region c of the unit photoelectric conversion portion 75, to the second electrode layer 74 with high resistance to the current collection hole 79, is long, which results in large current collection loss.

In contrast, as illustrated in FIG. 1, in the thin-film solar cell 10 according to this embodiment, the first linearly removed portion 21 is formed in a straight line, similar to the thin-film solar cell according to the related art, but the second linearly removed portion 22 has a bent portion 22a. Specifically, in this embodiment, the second linearly removed portion 22 has a bent structure that is bent two times at an angle of 90° on both sides in the horizontal direction of FIG. 1 (see exploded view (d) in FIG. 2), in order to expand the second overlap region in which the current collection holes 19 can be arranged while ensuring the first overlap region in which the connection holes 20 are arranged, as compared to the related art.

That is, in the this embodiment, the second linearly removed portion 22 is bent (includes the bent portion 22a) so as to include a region in which the rear electrode layer 18 forming each unit cell (UC) is opposite to (overlaps) the entire corresponding unit photoelectric conversion portion (15) or most of the corresponding unit photoelectric conversion portion (15) with the insulating substrate 11 interposed therebetween in a plan view, while ensuring the first overlap region having the connection holes 20 arranged therein on both sides (region D) of the unit cell in the horizontal direction of FIG. 1.

That is, in each unit cell (UC), the rear electrode layer 18 includes a bent portion that forms the first overlap region (the region in which the connection holes 20 are arranged; the region D in FIG. 1) in an adjacent unit cell. Specifically, the rear electrode layer 18 includes protruding portions 18a on both sides of each unit cell in the horizontal direction of FIG. 1. The protruding portion 18a partially protrudes toward an adjacent unit cell to form the first overlap region (the region in which the connection holes 20 are arranged). In each unit cell (UC), the second overlap region (region E in FIG. 1) in which the current collection holes 19 can be arranged is the entire unit photoelectric conversion portion (15) or most of the unit photoelectric conversion portion (15). Therefore, in the thin-film solar cell 10 according to this embodiment, the region in which the current collection holes 19 can be arranged is larger than that of the thin-film solar cell according to the related art. Therefore, it is possible to arrange a desired number of current collection holes 19 at the desired positions of the photoelectric conversion portion (second electrode layer 14) according to the manufacturing conditions of the thin-film solar cell. In this way, for example, it is possible to reduce the travel distance of the carriers generated from the photoelectric conversion portion to the second electrode layer 74 with high resistance and reduce current collection loss.

The shape of the second linearly removed portion 22 is not limited to that in this embodiment. For example, the second linearly removed portion 22 may not bend at a right angle, but it may be obliquely bent, it may include a curve, or it may be a curve bent at some portions, which is included in the meaning of “bent portion” in the specification. In addition, the second linearly removed portion 22 may be formed in a straight line and the first linearly removed portion 21 may have a bent portion. Alternatively, each of the first linearly removed portion 21 and the second linearly removed portion 22 may have a bent portion.

For example, in each unit cell (UC), at least one of the first linearly removed portion 21 and the second linearly removed portion 22 may have a bent portion such that the entire unit photoelectric conversion portion (15) or most of the unit photoelectric conversion portion (15) is the second overlap region in which the current collection holes 19 can be arranged. As a result, in each unit cell (UC), at least one of the first electrode layer 21 and the rear electrode layer 18 has a bent portion such that the entire unit photoelectric conversion portion (15) or most of the unit photoelectric conversion portion (15) is opposite to (overlaps) the rear electrode layer 18 with the insulating substrate 11 interposed therebetween.

When the first linearly removed portion 21 or the second linearly removed portion 22 has a bent portion, it is preferable that the bent portion be disposed near the connection holes 20 and in a region in which the second electrode layer 14 is not formed. The region in which the second electrode layer 14 is not formed includes a region of the front surface of the insulating substrate 11 in which the second electrode layer 14 is not formed and a region of the rear surface of the insulating substrate 11 corresponding to the region. When the first linearly removed portion 21 has a bent portion, the region in which the second electrode layer 14 is not formed corresponds to the former region. When the second linearly removed portion 22 has a bent portion, the region in which the second electrode layer 14 is not formed corresponds to the latter region. When the bent portion of the first linearly removed portion 21 or the second linearly removed portion 22 is disposed in the region in which the second electrode layer 14 is not formed, it is possible to increase an area of the region (second overlap region) in which the current collection holes 19 can be arranged.

In this embodiment, each of the layers provided on the front and rear surfaces of the insulating substrate 11 is linearly removed to form the first linearly removed portion 21 and the second linearly removed portion 22, thereby forming multiple unit cells (UC), each having the photoelectric conversion portion 15 formed on the front surface of the insulating substrate 11 and the rear electrode layer 18 formed on the rear surface of the insulating substrate 11, on the insulating substrate 11. However, the invention is not limited thereto. For example, a mask may be used to form each layer on the front surface and the rear surface of the insulating substrate 11 to form multiple unit cells on the insulating substrate 11. In this case, portions in which each layer is not formed due to the mask correspond to the first linearly removed portion 21 and the second linearly removed portion 22.

B. Distribution of Current Collection Holes

In order to examine the optimal arrangement of the current collection holes, the output characteristics of the thin-film solar cell were simulated considering area loss and current collection loss. The “area loss” means a reduction in the amount of generated current corresponding to a reduction (that is, a reduction in the total area of the current collection holes) in the power generation area due to the current collection holes, and the “current collection loss” means power loss occurring when the carriers generated from the photoelectric conversion portion move through the second electrode layer (transparent electrode layer) and/or when the carriers pass through the current collection holes. It is considered that the current collection loss is particularly affected by, for example, the arrangement or size of the current collection holes and the sheet resistance of the second electrode layer. The simulation was performed using a finite element method to analyze a current in each mesh region, thereby calculating a voltage drop, and the current-voltage characteristics (I-V characteristics) of the thin-film solar cell were calculated. The region in which the current collection holes can be arranged is the second overlap region in which the photoelectric conversion portion and the rear electrode layer forming each unit cell are opposite to each other with the insulating substrate interposed therebetween, and corresponds to the region E (rectangular region) in FIG. 1. Under some conditions, a thin-film solar cell actually having the SCAF structure was manufactured and the characteristics thereof were checked.

First, the number of rows of the current collection holes arranged in the region E was examined.

Specifically, the outputs of the thin-film solar cell were compared with changes in the number of rows of the current collection holes and with a constant value of the percentage of the total area of the current collection holes relative to the total area of the unit photoelectric conversion portion (power generation region) (hereinafter, referred to as an “aperture ratio”). In the following description, a direction along the long side of the region E is referred to as the “X direction” and a direction along the short side of the region E is referred to as the “Y direction.” The “number of rows” corresponds to the number of current collection holes in the Y direction.

When the aperture ratio is constant, area loss is constant. Therefore, the difference between the outputs of the thin-film solar cell (that is, the difference between the conversion efficiencies) depends on the arrangement of the current collection holes. Here, the number of rows of the current collection holes was changed at three aperture ratios (1%, 2%, and 4%) to compare the outputs of the thin-film solar cell. The diameter of the current collection hole was fixed to 1 mm and the number of current collection holes was adjusted to obtain each aperture ratio. In this examination, the outputs (Pmax) of the thin-film solar cell obtained when the region E (rectangular region) in which the current collection holes could be arranged had a size of 195.6 mm (X)×26.8 (Y) mm and the sheet resistances of the second electrode layer were 20 Ω, 50 Ω, and 100 Ω at each aperture ratio, were calculated.

Specifically, multiple current collection holes were arranged in the region E according to the following processes (1) to (4) and the outputs (Pmax) of the thin-film solar cell in the arrangements of the current collection holes were calculated and compared.

(1) The number n of rows of the current collection holes is determined and the region E is divided into (n+1) regions in the Y direction. For example, when five rows of current collection holes are arranged, 26.8/(5+1)=4.47 is obtained. Therefore, five parting lines (hereinafter, referred to as “first parting lines”) parallel to the long side of the region E are arranged at an interval of 4.47 mm in the Y direction and the region E is divided into six regions by the five first parting lines. In this way, six rectangular regions with a size of 195.6 mm×4.47 mm are formed in the region E.

(2) The number of current collection holes in each row is determined. Here, the total number of current collection holes corresponding to the aperture ratio is calculated, and the calculated total number is divided by the number n of rows to determine the number of current collection holes in each row. For example, when five rows of current collection holes are arranged at an aperture ratio of 2%, the aperture ratio of 2% corresponds to the formation of about 130 current collection holes (φ: 1 mm) in the region E and the number of current collection holes in each row is 130/5=26. In the examination, when the value obtained by dividing the total number of current collection holes by the number n of rows was not an integer, the total number of current collection holes was adjusted such that an integer closest to the calculated value was obtained.

(3) The region E is divided into {(the number of current collection holes in each row calculated in (2))+1} regions in the X direction. For example, when five rows of current collection holes are arranged at an aperture ratio of 2%, 195.6/(26+1)=7.24 is obtained. Therefore, 26 parting lines (hereinafter, referred to as “second parting lines”) parallel to the short side of the region E are arranged at an interval of 7.24 mm in the X direction and the region E is divided into 27 regions by the 26 second parting lines. As a result, the region E is divided into a lattice shape by the first parting lines and the second parting lines and 162 (=6×27) rectangular regions with a size of 7.24 mm×4.47 mm are formed in the region E.

(4) The current collection holes are arranged such that the centers of the current collection holes are disposed at the intersection points (lattice points) of the first parting lines and the second parting lines.

By (1) to (4), the current collection holes capable of achieving a predetermined aperture ratio are arranged in a lattice in the region E. In this way, a predetermined number of current collection holes are distributed in the region E, that is, a predetermined number of current collection holes are arranged in the entire region E. In addition, the multiple current collection holes are arranged at equal intervals in the X direction and the Y direction. The divided regions in (1) to (3) are different from the mesh region in the finite element method.

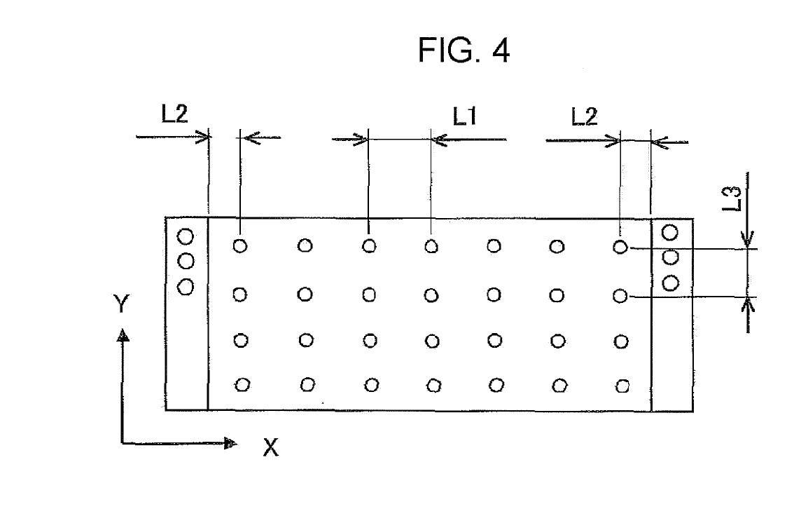

FIG. 4 is a diagram schematically illustrating multiple current collection holes arranged in a lattice (the number of rows is 4). In the arrangement of the current collection holes in a lattice illustrated in FIG. 4, the positions of all of the current collection holes in the X direction are adjusted such that the distance (L2) from both ends of the unit photoelectric conversion portion (power generation region) to the current collection holes closest to both ends in the X direction is almost half the distance (L1) between the current collection holes closest to each other in the X direction.

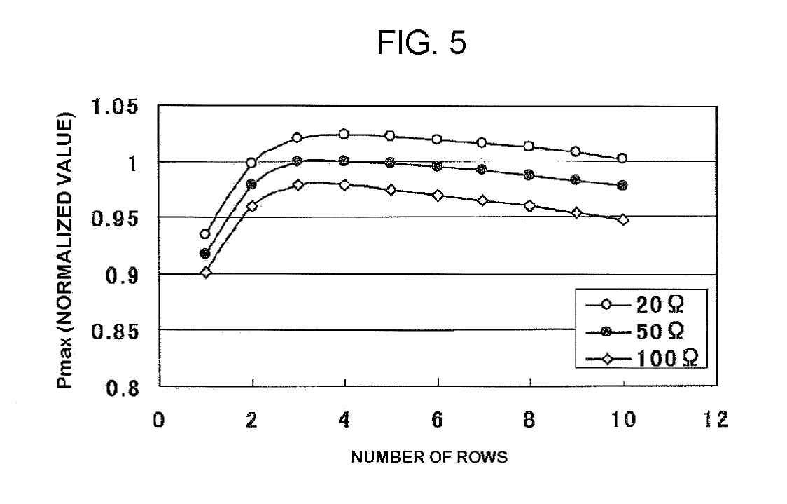

FIG. 5 illustrates the relationship between the number of rows of the current collection holes and the calculated output (Pmax) of the thin-film solar cell when the aperture ratio is 2%. In FIG. 5, the output (Pmax) is normalized to 1.0 when the number of rows of the current collection holes is 4 and the sheet resistance of the second electrode layer is 50 Ω.

As illustrated in FIG. 5, in the case of the aperture ratio of 2%, the output (Pmax) of the thin-film solar cell is the maximum at any sheet resistance value when the number of rows of the current collection holes is 3 or 4. As the sheet resistance of the second electrode layer increases, the output of the thin-film solar cell is reduced.

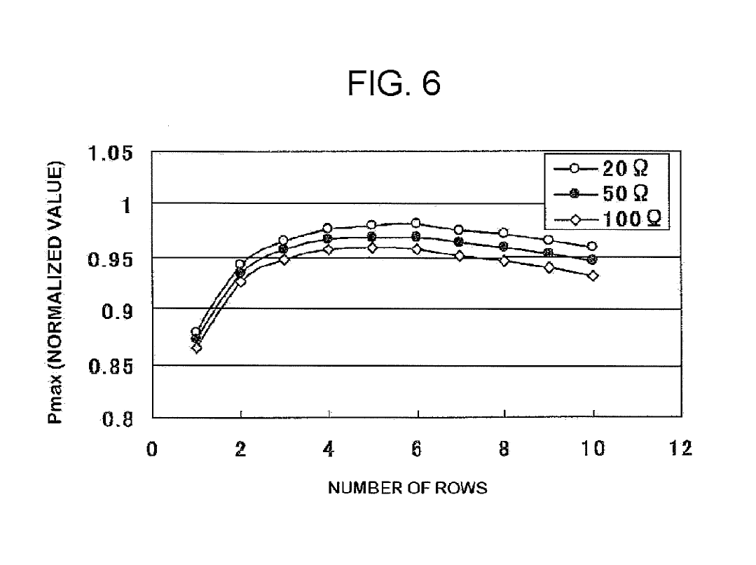

FIG. 6 illustrates the relationship between the number of rows of the current collection holes and the calculated output (Pmax) of the thin-film solar cell when the aperture ratio is 4%. In FIG. 6, the output (Pmax) is normalized to 1.0 when the aperture ratio is 2%, the number of rows of the current collection holes is 4, and the sheet resistance of the second electrode layer is 50 Ω as illustrated in FIG. 5.

As illustrated in FIG. 6, in the case of the aperture ratio of 4%, the output (Pmax) of the thin-film solar cell is the maximum at any sheet resistance value when the number of rows of the current collection holes is 5 or 6. The number of rows of the current collection holes where the output (Pmax) of the thin-film solar cell is the maximum is greater than that when the aperture ratio is 2% (see FIG. 5). In addition, a variation in the output of the thin-film solar cell due to a change in the sheet resistance of the second electrode layer is less than that when the aperture ratio is 2%.

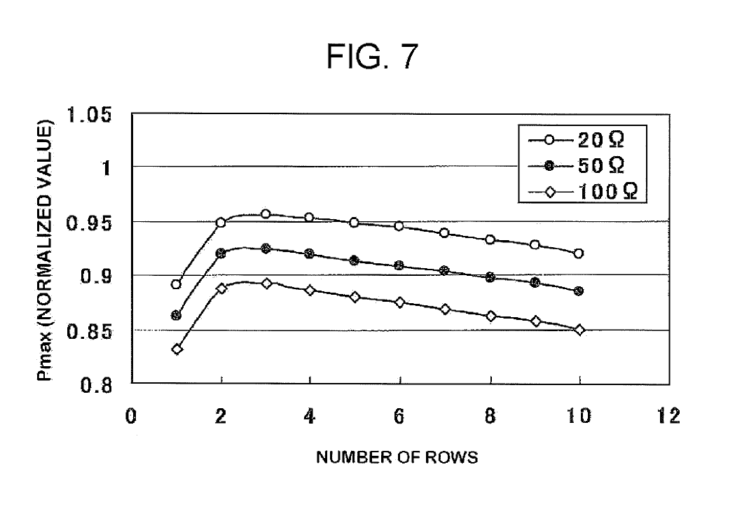

FIG. 7 illustrates the relationship between the number of rows of the current collection holes and the output (Pmax) of the thin-film solar cell when the aperture ratio is 1%. In FIG. 7, the output (Pmax) is normalized to 1.0 when the aperture ratio is 2%, the number of rows of the current collection holes is 4, and the sheet resistance of the second electrode layer is 50 Ω as illustrated in FIG. 5.

As illustrated in FIG. 7, in the case of the aperture ratio of 1%, the output (Pmax) of the thin-film solar cell is the maximum at any sheet resistance value when the number of rows of the current collection holes is 2 or 3. The number of rows of the current collection holes where the output (Pmax) of the thin-film solar cell is the maximum is smaller than that when the aperture ratio is 2% (see FIG. 5). In addition, a variation in the output of the thin-film solar cell due to a change in the sheet resistance of the second electrode layer is more than that when the aperture ratio is 2%.

As can be seen from FIGS. 5 to 7, as the aperture ratio increases, the number of rows of the current collection holes where the output (Pmax) of the thin-film solar cell is the maximum increases and a variation in the output of the thin-film solar cell due to a change in the sheet resistance of the second electrode layer is reduced.

For the gap between the current collection holes, the examination result proved that, in the case of the number of rows of the current collection holes where the output (Pmax) of the thin-film solar cell was the maximum at each aperture ratio, the gap between the current collection holes in the X direction was substantially equal to the gap between the current collection holes in the Y direction. That is, when multiple current collection holes are arranged such that the current collection holes are distributed in the entire region E and the gaps between the current collection holes in the X direction and the Y direction are substantially equal to each other, that is, when L1 is equal to L3 in FIG. 4, the output (Pmax) of the thin-film solar cell is the maximum at any aperture ratio.

That is, the optimal number of rows of the current collection holes varies depending on the aperture ratio (the number of current collection holes), but it is preferable that multiple current collection holes be arranged such that they are distributed in the overlap region (region E) between the unit photoelectric conversion portion and the unit rear electrode portion forming each unit cell and the gaps between the closest current collection holes are equal to each other at any aperture ratio.

A variation in the output of the thin-film solar cell due to a change in the sheet resistance is considered as follows. That is, as the aperture ratio increases, the number of current collection holes arranged in the region E increases and the gap between the current collection holes is reduced. As a result, a current collection area per current collection hole is reduced and the output of the thin-film solar cell is hardly affected by the sheet resistance of the second electrode layer. Therefore, as the aperture ratio increases, the variation in the output of the thin-film solar cell due to the change in the sheet resistance of the second electrode layer is reduced. However, as illustrated in FIGS. 5 to 7, at a sheet resistance of 20 Ω to 100 Ω, the numbers of rows of the current collection holes where the output (Pmax) of the thin-film solar cell is the maximum are almost equal to each other at each aperture ratio.

Therefore, it is preferable that multiple current collection holes be arranged such that they are distributed in the overlap region (region E) between the unit photoelectric conversion portion and the unit rear electrode portion forming each unit cell and the gaps between the closest current collection holes are equal to each other at any aperture ratio. The second electrode layer with a sheet resistance of 20 Ω to 100 Ω is generally used in the thin-film solar cell in practice. In FIGS. 5 to 7, the sheet resistance of the second electrode layer is in the range of 20 Ω to 100 Ω. However, calculation was performed at resistance values other than the above-mentioned resistance range, and the calculation result proved that substantially the same result as that in the current examination was obtained for the arrangement of the current collection holes where the maximum output (Pmax) was obtained.

As described above, it is preferable that multiple current collection holes be arranged such that they are distributed in the region E (that is, the region in which the current collection holes can be arranged) and the gaps between the closest current collection holes are equal to each other, regardless of the aperture ratio (the number of current collection holes) or the sheet resistance of the second electrode layer. According to this arrangement, it is possible to improve the conversion efficiency of the thin-film solar cell.

In practice, a thin-film solar cell was manufactured under some of the above-mentioned conditions and the output characteristics thereof were compared. As a result, substantially the same result as the above-mentioned simulation result was obtained.

However, as can be seen from the comparison among FIGS. 5 to 7, when the aperture ratio is 2% in the range of 1% to 4%, the output (Pmax) of the thin-film solar cell is the maximum. Therefore, it is preferable to set the aperture ratio to about 2% in the thin-film solar cell 10 according to the above-described embodiment that has substantially the same specifications as those of the currently examined thin-film solar cell. However, since the optimal aperture ratio is likely to vary depending on, for example, the sheet resistance of the second electrode layer, it is preferable that the same examination as the current examination be performed to set the aperture ratio even under the conditions (for example, the sheet resistance) different from the current conditions.

Next, the diameter of the current collection hole was examined. Specifically, the outputs of the thin-film solar cell were compared, changing the diameter of the current collection hole. Simulation was performed under the conditions that the aperture ratio was 2% (FIG. 5) and the number of rows of the current collection holes was 4.

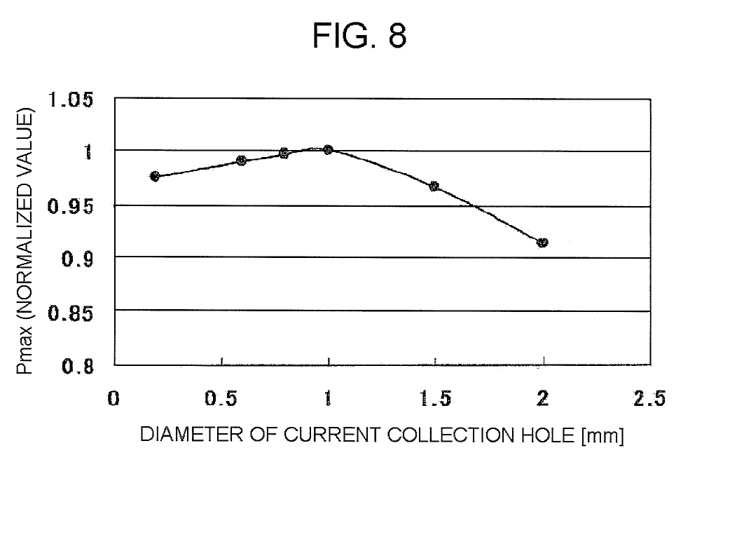

FIG. 8 illustrates the relationship between the diameter of the current collection hole and the output (Pmax) of the thin-film solar cell. In FIG. 8, the output (Pmax) is normalized to 1.0 when the aperture ratio is 2%, the number of rows of the current collection holes is 4, and the sheet resistance of the second electrode layer is 50 Ω, similar to FIGS. 5 to 7.

As illustrated in FIG. 8, when the diameter of the current collection hole is 1.0 mm, the output (Pmax) of the thin-film solar cell has the maximum value. As the diameter of the current collection hole increases, area loss increases. As the diameter of the current collection hole decreases (the circumferential length of the current collection hole is reduced), the resistance of the current collection hole increases. Therefore, in the currently examined thin-film solar cell, when the diameter of the current collection hole is greater than 1 mm, the influence of area loss is dominant and the output (Pmax) is reduced. When the diameter of the current collection hole is smaller than 1 mm, the resistive loss of the current collection hole is dominant and the output (Pmax) is reduced.

In FIG. 8, when the diameter of the current collection hole is in the range of 0.6 mm to 1.0 mm, the output (Pmax) of the thin-film solar cell is sufficiently high (Pmax is equal to or greater than 0.99). On the other hand, when the diameter of the current collection hole is greater than 1.0 mm, a variation in the output of the thin-film solar cell due to a change in the diameter of the current collection hole is large. Therefore, in the thin-film solar cell 10 according to the above-described embodiment that has substantially the same specifications as those of the currently examined thin-film solar cell, the diameter of the current collection hole may also be set in the range of 0.6 mm to 1.0 mm (preferably, 1.0 mm).

However, in the inner circumferential surface of the current collection hole, the second electrode layer (transparent electrode layer) and the fourth electrode layer overlap each other and are electrically connected to each other. The second electrode layer originally has high resistance. Therefore, when the resistance of the current collection hole is changed, the sheet resistance of the fourth electrode layer is dominant. When a material forming the fourth electrode layer or the thickness of the fourth electrode layer is changed, the resistance of the current collection hole is also changed even when the current collection holes have the same diameter. In the current examination, the resistance of the current collection hole (φ: 1 mm) was about 0.8 Ω. However, for example, when resistance of the current collection hole is reduced due to a change in the material of the fourth electrode layer or an increase in the thickness of the fourth electrode layer, the optimal diameter of the current collection hole is likely to be reduced. As the number of current collection holes increases, the amount of current collected in one current collection hole is reduced, and the resistive loss of the current collection hole is relatively reduced. As a result, the optimal diameter of the current collection hole is likely to be reduced. In this case, it is considered that the optimal diameter of the current collection hole does not greatly deviate from the range of 0.6 mm to 1 mm. However, the optimal diameter of the current collection hole smaller than the above-mentioned range may be found by the same examination as the current examination.

The diameter of each of the current collection holes arranged by the above-mentioned method was examined. The examination result proved that, when multiple current collection holes were arranged such that they were distributed in the region E and the gaps between the closest current collection holes were equal to each other, the output (Pmax) of the thin-film solar cell was the maximum, regardless of the diameter of the current collection hole, and the diameter of the current collection hole did not affect the optimal arrangement of the current collection holes. In addition, a thin-film solar cell was manufactured in practice and the outputs of the thin-film solar cell with respect to the diameters of the current collection holes were examined and compared. As a result, the same result as the above-mentioned simulation result was obtained.

Next, as a modification of the arrangement of multiple current collection holes (in a lattice shape), a structure in which multiple current collection holes were arranged in a staggered arrangement was examined. Specifically, in each of the above-mentioned examinations (FIGS. 5 to 8), for the current collection holes arranged in a lattice shape, each of the current collection holes in an even-numbered row (or an odd-numbered row) was shifted in the X direction such that each of the current collection holes in the even-numbered row (odd-numbered row) was disposed at the center of the minimum rectangle formed by four current collection holes in the odd-numbered rows (even-numbered rows). In this way, the current collection holes were arranged in a staggered arrangement shape.

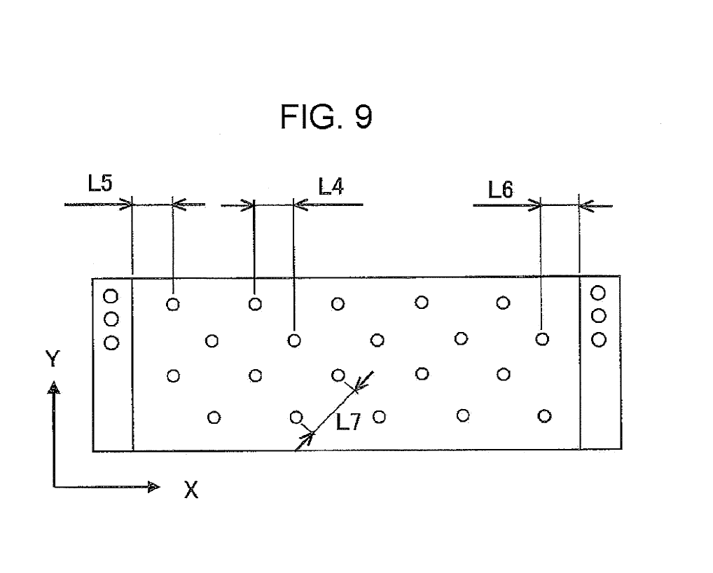

FIG. 9 is a diagram schematically illustrating a case in which multiple current collection holes are arranged in a staggered arrangement (the number of rows is 4). In the staggered arrangement illustrated in FIG. 9, the positions of all of the current collection holes in the X direction are adjusted such that the distance (L4) between the current collection holes closest to each other in the X direction and the distances (L5 and L6) from both ends of the unit photoelectric conversion portion (power generation region) to the current collection holes closest to both ends in the X direction are substantially equal to each other.

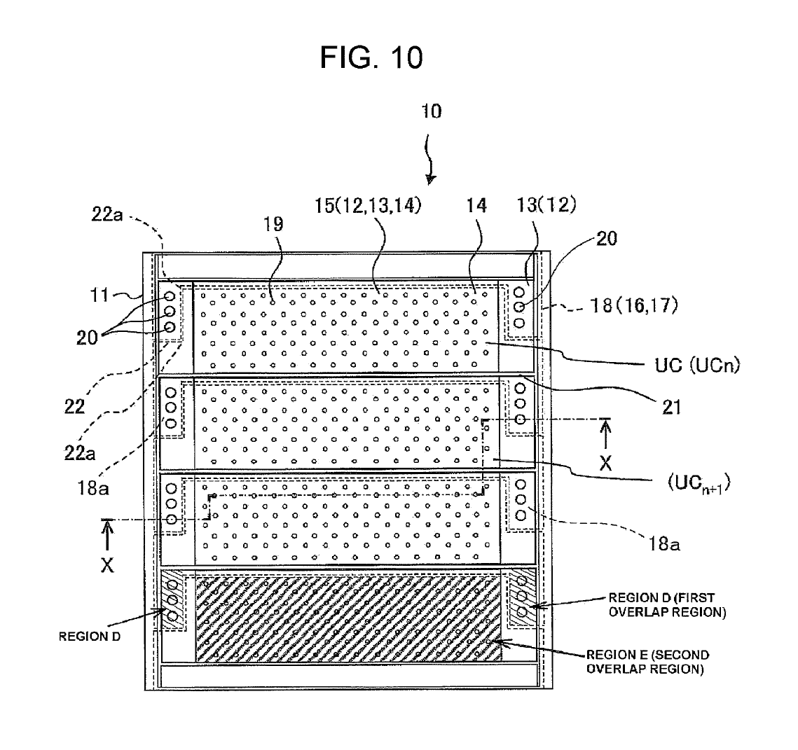

FIG. 10 illustrates the schematic structure of the thin-film solar cell 10 having multiple current collection holes 19 arranged in a staggered arrangement.

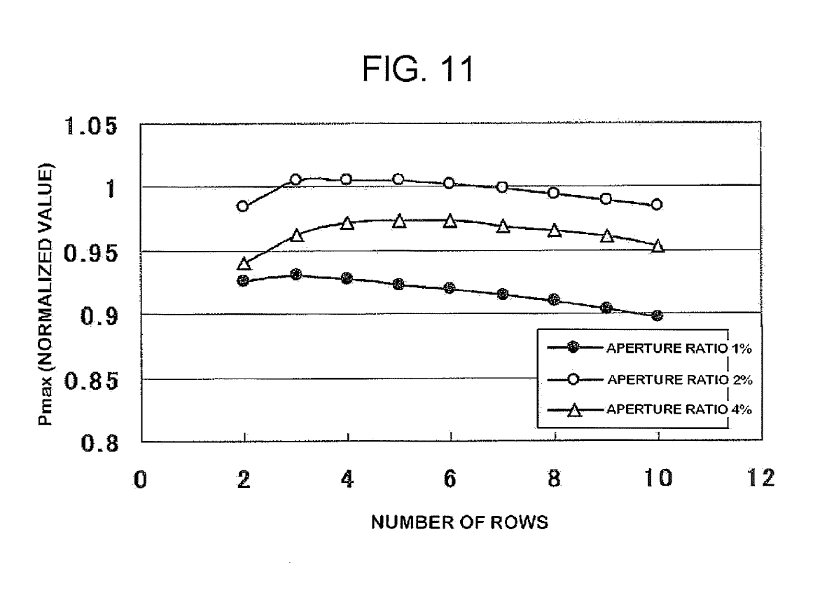

FIG. 11 illustrates the relationship between the output (Pmax) of the thin-film solar cell and the number of rows of the current collection holes when the current collection holes are arranged in a staggered arrangement. FIG. 11 illustrates the relationship only when the diameter of the current collection hole is 1 mm and the sheet resistance of the second electrode layer is 50 Ω. In FIG. 11, the output (Pmax) is normalized to 1.0 when the aperture ratio is 2%, the number of rows of the current collection holes is 4, and the sheet resistance of the second electrode layer is 50 Ω, similar to FIGS. 5 to 8.

As can be seen from FIG. 11, when the arrangement of the current collection holes was changed from a lattice shape to a staggered arrangement shape, the output (Pmax) of the thin-film solar cell increased, regardless of the number of rows. In addition, similar to the lattice-shaped arrangement, in the case of the number of rows of the current collection holes where the output (Pmax) of the thin-film solar cell was the maximum at each aperture ratio, the gaps between the closest current collection holes (L7 in FIG. 9) were equal to each other. In addition, for the staggered arrangement of the current collection holes, a thin-film solar cell was manufactured in practice and was then examined and compared in the same way as described above. As a result, the same result as the above-mentioned simulation result was obtained.

The examination result proved that it was preferable that, in the thin-film solar cell, at least multiple current collection holes be arranged so as to be uniformly distributed in the overlap region (region E) between the unit photoelectric conversion portion and the unit rear surface electrode portion forming each unit cell. Specifically, multiple current collection holes are arranged in a lattice or staggered arrangement such that the gaps between the closest current collection holes are equal to each other. It is possible to appropriately select whether to arrange multiple current collection holes in a lattice or staggered arrangement according to, for example, the number of current collection holes, or the size and shape of the region in which the current collection holes can be arranged. Considering current collection loss, it is preferable that the distance from both ends of the unit photoelectric conversion portion to the current collection hole closest to both ends be equal to or smaller than the gap between the current collection holes closest to each other.

In the above-mentioned case, the method of arranging the current collection holes was examined, in which the region (rectangular region E) in which the current collection holes could be arranged had a size of 195.6 mm×26.8 mm. However, even when the shape or size of the region in which the current collection holes can be arranged is changed, the above-mentioned series of examinations may be performed to find the optimal arrangement of the current collection holes. When the shape or size of the region in which the current collection holes can be arranged is changed, the optimal number of rows of the current collection holes or the optimal aperture ratio (the number of current collection holes) is changed. From the above-mentioned examination, it is considered that the following point is not changed: when multiple current collection holes are arranged such that they are distributed in the second overlap region (rectangular region E) in which the current collection holes can be arranged and the gaps between the closest current collection holes are equal to each other, it is possible to improve conversion efficiency.

In the thin-film solar cell having the SCAF structure, a change in the shape or size of the region in which the current collection holes can be arranged includes a change in the shape of the connection hole or a peripheral region (mask region) thereof and a change in the shape of the first linearly removed portion or the second linearly removed portion, in addition to a simple change in the shape or size of the region. As such, in the thin-film solar cell having the SCAF structure, the region in which the current collection holes can be arranged varies depending on the connection holes, the first linearly removed portion, and the second linearly removed portion. Therefore, it is necessary to perform simulation considering the above-mentioned variation to determine the optimal arrangement of the current collection holes. In addition, it is preferable to set the size of the connection hole or the number of connection holes considering area loss due to the connection holes and the resistive loss of the connection holes.

The thin-film solar cell having multiple unit cells formed on one insulating substrate has been described above, but the invention is not limited thereto. For example, multiple unit cells are not formed on one insulating substrate, but the unit cells may be formed on multiple insulating substrates. That is, any thin-film solar cell having a structure in which multiple unit cells are connected in series to one another falls within in the scope of the invention.

It will be apparent to one skilled in the art that the manner of making and using the claimed invention has been adequately disclosed in the above-written description of the exemplary embodiments taken together with the drawings. Furthermore, the foregoing description of the embodiments according to the invention is provided for illustration only, and not for limiting the invention as defined by the appended claims and their equivalents.

It will be understood that the above description of the exemplary embodiments of the invention are susceptible to various modifications, changes and adaptations, and the same are intended to be comprehended within the meaning and range of equivalents of the appended claims.

What is claimed is:

1. A thin-film solar cell comprising:
an insulating substrate; and
a plurality of unit solar cells, each unit solar cell including a photoelectric conversion portion and a rear electrode layer, the photoelectric conversion portion having a first electrode layer, a photoelectric conversion layer, and a second transparent electrode layer, sequentially stacked on a front surface of the insulating substrate, the rear electrode layer being stacked on a rear surface of the insulating substrate,
wherein each unit solar cell has a first overlap region in which a portion of the first electrode layer, taken from a plan view, overlaps with a portion of the rear electrode layer of an adjacent unit solar cell that is adjacent to each unit solar cell, with the insulating substrate interposed therebetween, said portion of the first electrode layer is not covered by the second transparent electrode layer,
wherein the first electrode layer of each unit solar cell and the rear electrode layer of the adjacent unit solar cell are electrically connected to each other in the first overlap region through at least one connection hole passing through the insulating substrate, thereby connecting the plurality of unit solar cells in series,
wherein the second electrode layer and rear electrode layer of each unit solar cell are electrically connected to each other through a plurality of current collection holes passing through the insulating substrate, and
wherein each unit solar cell has a second overlap region in which the photoelectric conversion portion and the rear electrode layer of each unit solar cell, taken from a plan view, overlap with each other with the insulating substrate interposed therebetween, and the plurality of current collection holes are distributed in the second overlap region, and
wherein distances from each of the current collection holes to a current collection hole that is most adjacent to said each of the current collection holes are substantially the same.

2. The thin-film solar cell according to claim 1, wherein the photoelectric conversion portions of two adjacent unit solar cells are separated from each other by a first removal line defined by a portion of the front surface of the insulating substrate directly on which the photoelectric conversion portion is not disposed, and the rear electrode layers of two adjacent unit solar cells are separated by a second removal line defined by a portion of the rear surface of the insulating substrate directly on which the rear electrode layer is not disposed.

3. The thin-film solar cell according to claim 2, wherein the first removal line is a straight line.

4. The thin-film solar cell according to claim 2, wherein the rear electrode layer of each unit solar cell, taken from a plan view, includes a protruding portion which protrudes outward from the remaining portion of the rear electrode layer of each unit solar cell, and
wherein said portion of the first electrode layer in the first overlap region overlaps with the protruding portion of the rear electrode layer of the adjacent unit solar cell.

5. The thin-film solar cell according to claim 4, wherein the first electrode layer of each unit solar cell, taken from a plan view, has a protruding portion that protrudes outward from the remaining portion of the first electrode layer, and
wherein the protruding portion of the first electrode layer of each unit solar cell overlaps with a portion of the rear electrode layer of the adjacent unit solar cell.

6. The thin-film solar cell according to claim 4, wherein the second removal line includes a bent portion having a bent structure that is bent two times at the angle of 90° on both sides thereof in leftward and rightward directions, respectively.

7. The thin-film solar cell according to claim 4, wherein the bent portion defines an outline of the protruding portion of the rear electrode layer, and the bent portion is disposed near the at least one connection hole of each unit solar cell.

8. The thin-film solar cell according to claim 1, wherein the plurality of current collection holes of each unit solar cell are arranged in a lattice in the second overlap region of each unit solar cell, and
the second overlap region of each unit solar cell, taken from a plan view, has a first side extending in a first direction and a second side extending in a second direction, the first side being longer than the second side, the first direction being perpendicular to the second direction.

9. The thin-film solar cell according to claim 8, wherein the photoelectric conversion portion of each unit solar cell, taken from a plan view, has an end side extending in the second direction, and
wherein a distance in the first direction from the end side to a current collection hole closest to the end side is about half a distance in the first direction between two most adjacent current collection holes.

10. The thin-film solar cell according to claim 8, wherein distances in the first direction between two adjacent current collection holes that are spaced from each other in the first direction are substantially equal to distances in the second direction between two adjacent current collection holes that are spaced apart from each other in the second direction.

11. The thin-film solar cell according to claim 1, wherein the plurality of current collection holes of each unit solar cell are arranged in a staggered arrangement in the second overlap region of each unit solar cell.

12. The thin-film solar cell according to claim 1, wherein the second overlap region of each unit solar cell, taken from a plan view, has a first side extending in a first direction and a second side extending in a second direction, the first side being longer than the second side, the first direction being perpendicular to the second direction, and
wherein five adjacent current collection holes are arranged, such that a rectangle shape is formed by four of the five adjacent current collection holes, the four holes being respectively disposed at four corners of the rectangle, the remaining one hole of the five adjacent holes being disposed at the center of the rectangle, two opposite sides of the rectangle being parallel to the first direction, two opposite sides of the rectangle being parallel to the second direction.

13. The thin-film solar cell according to claim 12, wherein the photoelectric conversion portion of each unit solar cell, taken from a plan view, has an end side extending in the second direction, and
wherein a distance in the first direction from the end side to a current collection hole closest to the end side is substantially equal to a distance in the first direction between two most adjacent current collection holes.

14. The thin-film solar cell according to claim 1, wherein:
taken from a plan view, in each unit solar cell, the photoelectric conversion portion and the rear electrode layer respectively have an upper end and a lower end opposite to the upper end, the lower end facing a further upper end of an adjacent one of the unit solar cells; and
taken from a plan view, in each unit solar cell, the upper end of the photoelectric conversion portion is aligned with the upper end of the rear electrode layer, and the lower end of the photoelectric conversion portion is aligned with the lower end of the rear electrode layer.
